(19) United States
(12) Patent Application Publication
(10) Pub. No.: US 2009/0174028 A1
(43) Pub. Date: Jul. 9, 2009

(54) Fuse in a Semiconductor Device and Method for Forming the Same

(75) Inventor: Myung Kuk Mun, Icheon-Si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/342,256

(22) Filed: Dec. 23, 2008

(30) Foreign Application Priority Data
Jan. 7, 2008 (KR) 10-2008-0001903

(51) Int. Cl. H01L 23/525; H01L 21/71

(52) U.S. Cl. 257/529; 438/132; 257/E23.149; 257/E21.536

(57) ABSTRACT

A fuse of a semiconductor device, and a method for forming the same, wherein the fuse includes a zigzag-shaped fuse portion on a planar structure, thereby reducing energy when the fuse is cut. The laser irradiation time can be reduced, thereby preventing fuse cutting defects and damages on a neighboring fuse. Also, a laser point where a laser is irradiated is not affected by misalignment, thereby improving characteristics of the fuse.

### CROSS-REFERENCE TO RELATED APPLICATION

Priority to Korean patent application number 10-2008-0001903 filed Jan. 7, 2008, the entire disclosure of which is incorporated by reference, is claimed.

### BACKGROUND OF THE INVENTION

The invention relates to a fuse of a semiconductor device, and a method for forming the same.

If at least one memory cell of a memory array of a semiconductor device has a defect due to a high degree of integration of the semiconductor device, the whole device is regarded as being defective and discarded, thereby decreasing the device yield.

To overcome this problem, semiconductor devices are designed with redundancy cells so that a defective cell may be replaced with a redundancy cell resulting in repair of the whole memory, thereby improving yield.

The repair operation with a redundancy cell is performed to identify a defective memory cell through a test after wafer processing and to replace the corresponding address with an address signal of a spare, redundancy cell.

When an address signal corresponding to a defective line is inputted in the repair operation, the defective line is substituted by a redundancy line.

In order to perform the above repair process for repairing the defective circuit, after a semiconductor device is fabricated, an oxide film over a metal fuse is removed to open a fuse box, and a laser is irradiated into the corresponding metal fuse to cut a metal fuse.

A wire disconnected by laser irradiation is referred to as a metal fuse, and the disconnected site and its surrounding region are referred to as a fuse box.

FIG. 1 is a plane diagram illustrating a conventional fuse of a semiconductor device.

Referring to FIG. 1, a plurality of fuses 110 are patterned in a fuse region of a semiconductor substrate (not shown) including a lower structure.

The fuse 110 is deposited when a metal line or a plate (not shown) of a cell region is formed, and formed by a subsequent patterning process. The plurality of fuses 110 are formed with a line/space type, respectively.

An interlayer insulating film (not shown) and a protecting film (not shown) are formed over the resulting structure including the fuse 110.

The protecting film (not shown) and the interlayer insulating film (not shown) are etched over the plurality of fuses 110 by a repair etching process using a fuse open mask, thereby forming a fuse box 100.

The corresponding fuse 110 is cut in a repair process using a laser.

The repair process cuts the corresponding fuse 110 by irradiating the fuse 110 with a size of a set laser beam.

It is preferable to locate a laser point 120 in the center region of the fuse 110.

However, the fuse 110 is formed with a large critical dimension, unlike other layers such as a gate and a bit line, for example. In order to cut the fuse having a large critical dimension, a laser must irradiate the fuse with high energy for a long time period, thereby increasing the probability of damage to a neighboring fuse.

FIG. 2 is a plane diagram illustrating a prior art fuse of a semiconductor device suggested to overcome the problem of the fuse of FIG. 1.

Referring to FIG. 2, a plurality of fuses 210 each having a smaller critical dimension than that of the fuse 110 of FIG. 1 are positioned in a fuse box 200.

A corresponding fuse 210 is cut by a repair process using a laser.

The repair process cuts the corresponding fuse 210 by irradiating a laser to the fuse 210 with a set laser beam having a selected size.

It is preferable to locate a laser point 220 in the center region of the fuse 210, as shown.

However, the laser may not precisely be aimed in the repair process, but may be misaligned in an X-axis direction or a Y-axis direction.

When the laser point 220 is misaligned in the Y-axis direction, there is no problem. However, if the laser point 220 is misaligned in the X-axis direction as shown in ‘A’, the fuse may not be completely cut, or the neighboring fuse may be damaged.

In the conventional fuse of the semiconductor device and the conventional method for forming the same, when the critical dimension of the fuse is large, a laser is irradiated with high energy for a long time to cut the fuse. When the critical dimension of the fuse is smaller, if the laser is not precisely aimed, the fuse may not be cut or may the neighboring fuse may be damaged.

### BRIEF SUMMARY OF THE INVENTION

Various embodiments of the disclosure are directed at providing a fuse of a semiconductor device and a method for forming the same.

According to an embodiment of the invention, a fuse of a semiconductor device comprises a zigzag-shaped fuse portion over a planar structure.

The fuse preferably has a line type (i.e., a linear shape). The zigzag-shaped fuse portion repeatedly extends along a major axis direction of the fuse.

The zigzag-shaped fuse portion preferably comprises: a plurality of first patterns arranged parallel to a minor axis direction of the fuse, and a plurality of second patterns parallel to a major direction of the fuse connecting adjacent first patterns, and together with the first patterns forming the zigzag shape. The second patterns preferably have a shorter length than the first patterns. The first patterns preferably have a length corresponding to the critical dimension of the minor direction of the fuse.

The zigzag-shaped fuse portion is preferably located in a center portion of the fuse, or in the entire region of the fuse, with respect to the major axis direction.

According to an embodiment of the invention, a method for forming a fuse of a semiconductor device comprises: forming a fuse having a zigzag-shaped fuse portion on a planar structure over a semiconductor substrate; forming an interlayer insulating film and a protecting film over the resulting structure including the fuse; and etching the protecting film and the interlayer insulating film by a repair etching process to expose the fuse portion and form a fuse box.

The zigzag-shaped fuse portion preferably repeatedly extends along a major axis direction of the fuse. The zigzag-shaped fuse portion preferably includes a first pattern parallel to a minor axis direction of the fuse and a second pattern parallel to the major axis direction, the second pattern being shorter then the first pattern.

The first pattern preferably is formed to have a length corresponding to a critical dimension of the minor axis direction of the fuse. The critical dimension of the minor axis direction of the first pattern and the second pattern is preferably smaller than that of the minor axis direction of the fuse.

The zigzag-shaped fuse portion is preferably formed in the center portion of the fuse, or in the entire region of the fuse, with respect to the major axis direction.

### BRIEF DESCRIPTION OF THE DRAWINGS

FIGS. 1 and 2 are plane diagrams illustrating a conventional fuse of a semiconductor device.

FIGS. 3 and 4 are plane diagrams illustrating a fuse of a semiconductor device according to an embodiment of the invention.

### DESCRIPTION OF SPECIFIC EMBODIMENTS

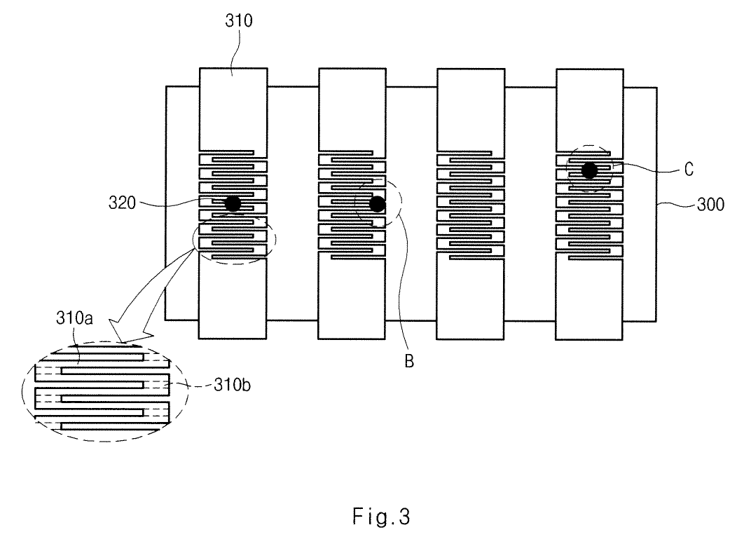

FIG. 3 is a plane diagram illustrating a fuse of a semiconductor device according to an embodiment of the invention.

Referring to FIG. 3, a plurality of fuses 310 are patterned in a fuse region of a semiconductor substrate (not shown) including a lower structure.

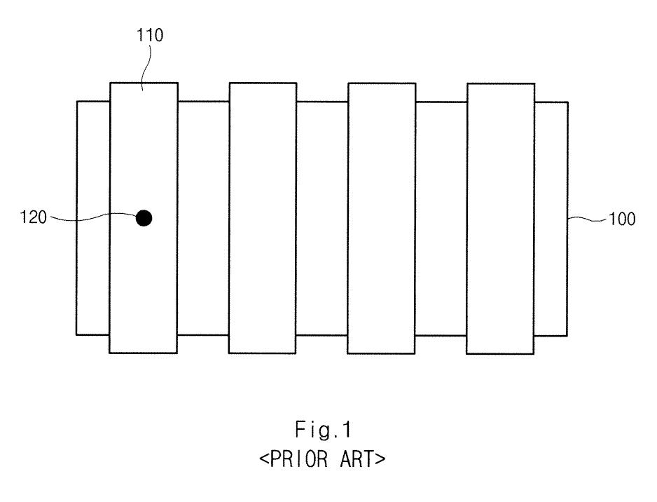

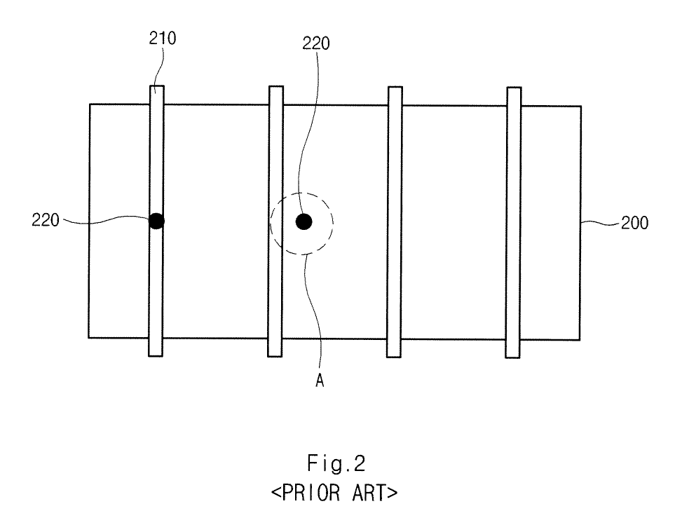

The fuse 310 is deposited when a metal line or a plate (not shown) of a cell region is formed, and formed by a subsequent patterning process. The illustrated plurality of fuses 310 are formed with a line/space type, respectively. The critical dimension of the fuse 310 is identical with that of the fuse of FIG. 1. The fuse 310 includes a zigzag-shaped (i.e., a line, course, or progression characterized by sharp turns first to one side and then to the other) fuse portion on a planar structure. The zigzag-shaped fuse portion is preferably formed in the center region which is a blowing region of the fuse 310.

The zigzag-shaped fuse portion preferably includes a plurality of first patterns 310a extending parallel to a minor axis direction of the fuse 310, and a plurality of second patterns 310b each extending between and connecting the first patterns 310a, preferably parallel to a major axis direction of the fuse. The first patterns 310a and the second patterns 310b may be connected with one line, due to the zigzag shape. The first pattern 310a preferably has the same length as the minor axis direction of the fuse 310, thereby securing a margin in an X-direction or a Y-direction where the laser is irradiated. The second pattern 310b is preferably shorter than the first pattern 310a. The critical dimension of the minor axis direction of the first pattern 310a and the second pattern 310b is preferably smaller than that of the minor axis direction of the fuse 310.

Although not shown here, the zigzag-shaped fuse portion can include a plurality of third patterns arranged in parallel to a major axis direction of the fuse 310, and a plurality of fourth patterns extending between and connecting the third patterns. The fourth patterns are preferably formed in a zigzag shape, so that the third pattern and the fourth pattern may be connected with one line.

An interlayer insulating film (not shown) and a protecting film (not shown) are formed over the resulting structure including the fuse 310.

The protecting film (not shown) and the interlayer insulating film (not shown) over the fuse 310 are etched by a repair etching process using a fuse open mask, thereby forming a fuse box 300. Preferably, the interlayer insulating film (not shown) remains over the fuse 310.

The corresponding fuse 310 is cut by a repair process using a laser.

The repair process cuts the corresponding fuse 310 by irradiating the fuse 310 using a laser beam with a set size.

A laser point 320 is located in the center region of the fuse 310. The laser beam is preferably set to have a size greater than the critical dimension of the first pattern 310a and the second pattern 310b and positioned in the zigzag-shaped fuse portion of the fuse 310.

Since the zigzag-shaped fuse portion has a fine critical dimension, laser radiation with only relatively small energy for a relatively short time is required to cut the corresponding fuse 310.

The first pattern 310a of the zigzag-shaped fuse portion is extended by the critical dimension of the minor axis direction of the fuse. Even when the laser point 320 is misaligned in an X-axis direction (see ‘B’) or in a Y-axis direction (see ‘C’), the corresponding fuse 310 is cut.

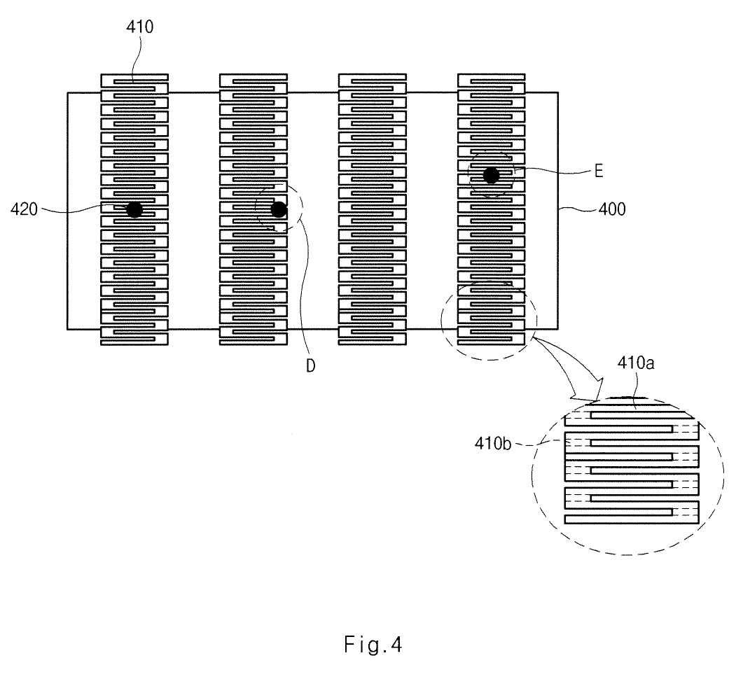

FIG. 4 is a plane diagram illustrating a fuse of a semiconductor device according to another embodiment of the invention.

Referring to FIG. 4, a plurality of fuses 410 are positioned in a fuse box 400 of a semiconductor substrate. The entire region of the fuse 410 includes a zigzag-shaped fuse portion on a plane structure as shown in FIG. 3.

The zigzag-shaped fuse portion includes a plurality of first patterns 410a arranged parallel to a minor axis direction of the fuse 410, and a plurality of second patterns 410b each extending between and connecting the first patterns 410a, preferably parallel to a major axis direction of the fuse. The second patterns 410b and the first patterns 410a are connected with one line. The second pattern 410b is preferably shorter than the first pattern 410a.

The zigzag-shaped fuse portion is preferably formed in the entire region of the fuse 410, i.e. along the entire fuse 410 extending in the major axis direction.

Although not shown here, the zigzag-shaped fuse portion can include a plurality of third patterns arranged parallel to a major axis direction of the fuse 410, and a plurality of fourth patterns each extending between and connecting the third patterns, preferably extending parallel to the major axis direction of the fuse. The fourth patterns and the third patterns may be connected with one line.

If the fuse 410 is formed as described above, even when the laser point 420 is misaligned in an X-axis direction (see ‘D’) or in a Y-axis direction (see ‘E’) in a laser repair process, the corresponding fuse 410 may be cut.

The above embodiments of the disclosure are illustrative and not limiting. Various alternatives and equivalents are possible. The invention is not limited by the type of deposition, etching polishing, and patterning steps describe herein, nor is the invention limited to any specific type of semiconductor device. For example, the disclosure may be implemented in a dynamic random access memory (DRAM) device or non volatile memory device. Other additions, subtractions, or modifications of the present disclosure are intended to fall within the scope of the appended claims.

What is claimed is:

1. A fuse of a semiconductor device, the fuse comprising a zigzag-shaped fuse portion over a planar structure.

2. The fuse according to claim 1, wherein the fuse has a linear shape.

3. The fuse according to claim 1, wherein the zigzag-shaped fuse portion comprises:
a plurality of first patterns parallel to a minor axis direction of the fuse; and
a plurality of second patterns parallel to a major axis direction of the fuse, each second pattern connecting two adjacent patterns, such that the first and second patterns together form a zigzag shape.

4. The fuse according to claim 3, wherein the second patterns are shorter than the first patterns.

5. The fuse according to claim 3, wherein the first pattern has a length corresponding to a critical dimension of the minor axis direction of the fuse.

6. The fuse according to claim 1, wherein the zigzag-shaped fuse portion comprises:
a plurality of third patterns parallel to a major axis direction of the fuse; and
a plurality of fourth patterns parallel to a minor axis direction of the fuse, each fourth pattern connecting adjacent third patterns, such that the third and fourth patterns together form a zigzag shape.

7. The fuse according to claim 1, wherein the zigzag-shaped fuse portion is located in a center portion of the fuse.

8. The fuse according to claim 1, wherein the zigzag-shaped fuse portion is located in the entire region of the fuse.

9. A method for forming a fuse of a semiconductor device, the method comprising:
forming a fuse having a zigzag-shaped fuse portion disposed over a semiconductor substrate;
forming an interlayer insulating film and a protecting film over the resulting structure including the fuse; and
etching the protecting film and the interlayer insulating film by a repair etching process to expose the fuse portion and form a fuse box.

10. The method according to claim 9, wherein the zigzag-shaped fuse portion includes a first pattern parallel to a minor axis direction of the fuse and a second pattern parallel to a major axis direction, the second pattern being shorter than the first pattern.

11. The method according to claim 10, wherein the first pattern has a length corresponding to a critical dimension of the minor axis direction of the fuse.

12. The method according to claim 10, wherein a critical dimension of the minor axis direction of the first pattern and the second pattern is smaller than the critical dimension of the minor axis direction of the fuse.

13. The method according to claim 9, wherein the zigzag-shaped fuse portion includes a third pattern parallel to a major axis direction of the fuse and a fourth pattern parallel to the minor axis direction, the fourth pattern being shorter then the third pattern.

14. The method according to claim 9, wherein the zigzag-shaped fuse portion is formed in a center portion of the fuse.

15. The method according to claim 9, wherein the zigzag-shaped fuse portion is formed in the entire region of the fuse.
